(19) United States
(12) Patent Application Publication
(10) Pub. No.: US 2005/0275034 A1
(43) Pub. Date: Dec. 15, 2005

(54) A MANUFACTURABLE METHOD AND STRUCTURE FOR DOUBLE SPACER CMOS WITH OPTIMIZED NFET/PFET PERFORMANCE

(75) Inventors: Sadanand V. Deshpande, Fishkill, NY (US); Dominic J. Schepis, Wappingers Falls, NY (US); Brian L. Tessier, Poughkeepsie, NY (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 10/709,048

(22) Filed: Apr. 8, 2004

(51) Int. Cl. H01L 29/76; H01L 21/8238

(52) U.S. Cl. 257/369; 438/199

(57) ABSTRACT

Disclosed is a method and structure where a first spacer is formed and an NFET is implanted, and then a second spacer is formed and a PFET is implanted. A dry nitride etch is then performed which selectively removes the second spacer, stopping selectively on an etch stop. This all dry removal process is more manufacturable than a wet etch, since it can be controlled to etch at a slower rate and it is not isotropic. This leaves a double nitride spacer on the PFETs and a single nitride spacer on the NFETs, giving the optimal spacer for each type of device. Furthermore, before suicide formation, the etch stop film on the nitride is removed, leading to a silicide edge very close to the gates for the NFETs, which is optimum for NFETs. The double nitride spacer on the PFETs prevents the silicide from getting too close to the PFET gate, which is optimum for PFETs.

### BACKGROUND OF INVENTION

The invention generally relates to integrated circuit transistors and methods for forming the same and more particularly provides an improved methodology and structure that utilizes double spacers on one type of transistor and single spacers on the complementary type transistor to provide significant impurity and silicide spacing benefits corresponding to the different types of transistors.

### DESCRIPTION OF THE RELATED ART

The optimization of high performance CMOS (Complementary Metal Oxide Semiconductor) consists of getting the highest performance from both the NFET (N-type field effect transistor and PFET (P-type field effect transistor) devices. Often, as observed in CMOS, the best process for one device may cause lower performance in the other device. The NFET and PFET were found to each be optimum with a different sidewall spacer process. Unfortunately, the processes involved in building two different spacers on two different devices is challenging. The present invention provides a manufacturable way of optimizing the sidewalls on NFET and PFET devices separately, leading to the highest performance CMOS.

### SUMMARY OF INVENTION

The invention provides a method of simultaneously forming different types of transistors on a single substrate and a resulting structure. The method begins by forming first spacers adjacent gate conductors on the substrate. Next, a first mask is formed over regions of the substrate to be occupied by second-type transistors (e.g. PFETs). The invention implants a first-type impurity in portions of the substrate adjacent the first spacers of first-type transistors (e.g., NFETs) and removes the first mask.

This process continues by forming an etch stop layer on all of the first spacers, on the substrate, and on exposed portions of the gate conductors. Next, second spacers are formed on the etch stop layer. After this step, all of the gate conductors have double spacers. Then, the invention forms a second mask over regions of the substrate to be occupied by the NFETs, implants a second-type impurity in portions of the substrate adjacent the second spacers of the PFETs, and then removes the second mask.

After this, the invention forms a third mask over regions of the substrate to be occupied by the PFETs, removes the second spacers from the NFETs, and then removes the third mask. Finally, the exposed areas of the substrate and the gate conductors not covered by the first spacers and the second spacers are silicided.

The etch stop layer prevents the process of removing the second spacers from affecting the first spacers. Before forming the first spacers, extension impurities can be implanted in regions of the substrate adjacent the gate conductors. The first-type and second-type impurities comprise source/drain impurities.

This process produces an integrated circuit structure that has NFETs and PFETs on the same substrate. The NFETs have “first” gate conductors and the PFETs have “second” gate conductors. First spacers are adjacent the first gate conductors and the second gate conductors. An etch stop layer is on the first spacers that are adjacent the second gate conductors. Second spacers are adjacent the first spacers that are adjacent the second gate conductors. The etch stop layer is positioned between the first spacers and the second spacers.

The second spacers are only adjacent the first spacers that are adjacent the second gate conductors and the second spacers are not adjacent the first spacers that are adjacent the first gate conductors. Similarly, the etch stop layer is only on the first spacers that are adjacent the second gate conductors and the etch stop layer is not on the first spacers that are adjacent the first gate conductors.

First-type impurity implants are in areas of the substrate adjacent the first spacers of the first gate conductors, and second-type impurity implants are in areas of the substrate adjacent the second spacers of the second gate conductors. Because the second spacers extend beyond the first spacers in the PFETs, the first-type impurity is spaced closer to the first gate conductors than the second-type impurity is spaced from the second gate conductors. Thus, as shown below, the invention provides a method and structure where the first spacer is made and the NFET is implanted, and then a second spacer is formed and the PFET is implanted. A dry nitride etch is then performed which selectively removes the silicon nitride second spacer, stopping selectively on the etch stop. This all dry removal process is more manufacturable than a wet etch, since it can be controlled to etch at a slower rate and it is not isotropic. This leaves a double nitride spacer on the PFETs and a single nitride spacer on the NFETs, giving the optimal spacer for each type of device. Furthermore, before silicide formation, the etch stop film on the nitride is removed, leading to a silicide edge very close to the gates for the NFETs, which is optimum for NFETs. The double nitride spacer on the PFETs prevents the silicide from getting too close to the PFET gate, which is optimum for PFETs.

These, and other, aspects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF DRAWINGS

The invention will be better understood from the following detailed description with reference to the drawings, in which:

FIG. 1 is a schematic cross-sectional diagram of a partially completed integrated circuit structure according to the invention;

FIG. 2 is a schematic cross-sectional diagram of a partially completed integrated circuit structure according to the invention;

FIG. 3 is a schematic cross-sectional diagram of a partially completed integrated circuit structure according to the invention;

FIG. 4 is a schematic cross-sectional diagram of a partially completed integrated circuit structure according to the invention;

FIG. 5 is a schematic cross-sectional diagram of a partially completed integrated circuit structure according to the invention;

FIG. 6 is a schematic cross-sectional diagram of a partially completed integrated circuit structure according to the invention;

FIG. 7 is a schematic cross-sectional diagram of a partially completed integrated circuit structure according to the invention;

FIG. 8 is a schematic cross-sectional diagram of a partially completed integrated circuit structure according to the invention; and

FIG. 9 is a flowchart illustrating processing achieved with the invention.

### DETAILED DESCRIPTION

The present invention and the various features and advantageous details thereof are explained more fully with reference to the nonlimiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the present invention. The examples used herein are intended merely to facilitate an understanding of ways in which the invention may be practiced and to further enable those of skill in the art to practice the invention. Accordingly, the examples should not be construed as limiting the scope of the invention.

The invention creates different spacers on both the NFET and PFET devices. One method that is not necessarily publicly known is called double spacer, where a narrow spacer is put in place and the NFET is implanted. Then a second spacer is put in place and the PFET is implanted. PFETs use boron as an implant species, and the boron diffuses much faster than arsenic during heat cycles. This requires that the boron deep junction be placed further away from the gate than the arsenic deep junction, thus the need for multiple spacers. However, the subsequent cobalt silicide formation is limited by the distance of the final second spacer, which keeps this silicide at a distance of several hundred angstroms. The NFET has been shown to have the highest performance when the silicide is very much closer to the gate, so the double spacer technique does not produce the fastest NFET. If a single narrow spacer was used, the NFET would be optimized, but the close proximity of the silicide for the PFET, along with deep junction overrun will make a poor performance PFET.

In view of the foregoing, the invention provides a method and structure where the first spacer is made and the NFET is implanted. Then, a second spacer is formed and the PFET is implanted. The spacers can comprise, for example, nitride films using an LTO (low temperature oxide) underlayer as the etch stop. Finally, after the second spacer is formed and implanted, a mask is used to block off the PFETS and cover them with photoresist. A dry nitride etch is then performed which selectively removes the silicon nitride second spacer, stopping selectively on the LTO etch stop. The photoresist is then removed, leaving a double nitride spacer on the PFETs and a single nitride spacer on the NFETs, giving the optimal spacer for each type of device. Furthermore, before silicide formation, the LTO etch stop film on the nitride will be removed by HF, leading to a silicide edge very close to the gates for the NFETs while the double nitride spacer on the PFETs prevents the silicide from getting too close to the gate.

One particular process for forming the inventive structure is discussed below. A first spacer is formed on a CMOS gate structure, by depositing a film, which can be silicon dioxide, silicon nitride, or polysilicon and etching the film to form a spacer adjacent to the gate. The spacer is generally 20-50 nm wide. A thin oxide (LTO) or nitride film is then deposited as an etch stop to a thickness of approximately 50-200 A. A second spacer is formed by depositing a film, (again nitride for example) to a thickness of 20-50 nm and again is made into a spacer by anisotropic etching of the film. This forms a double spacer.

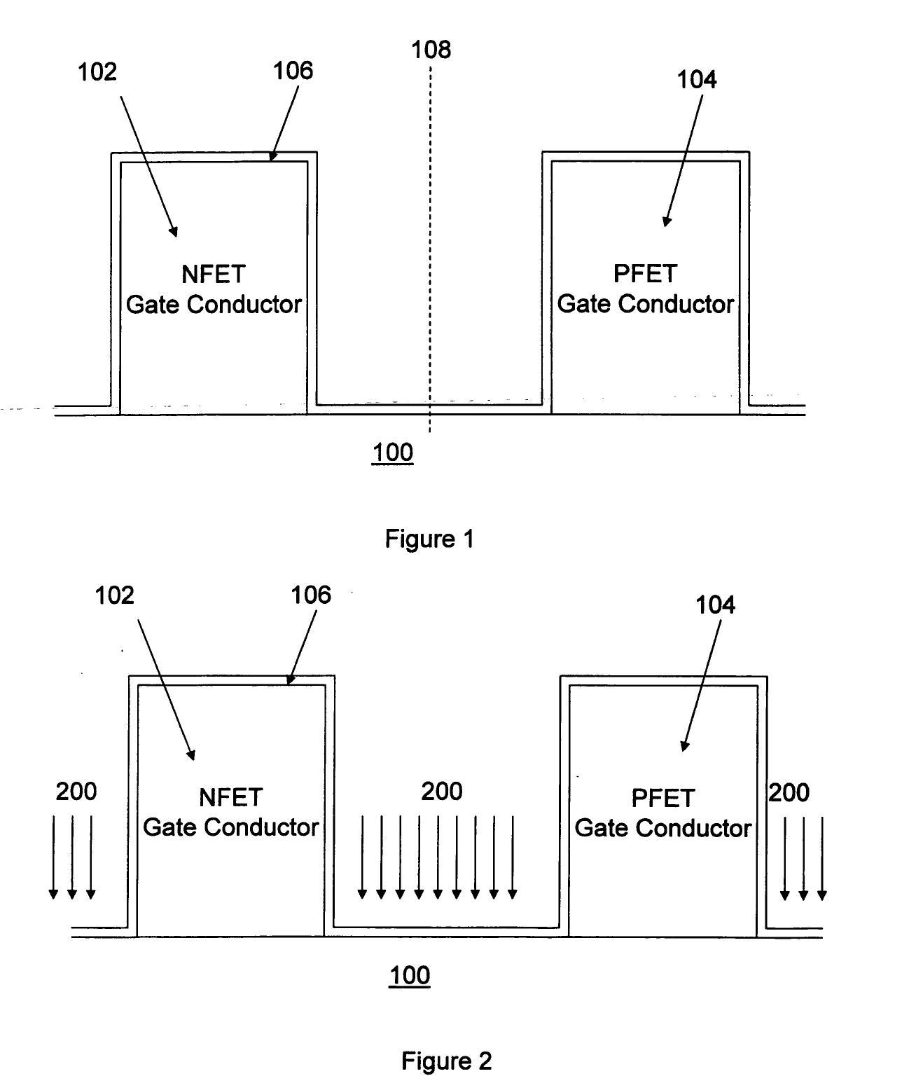

More specifically, as shown in FIG. 1, the invention forms gate conductors 102, 104 on a substrate 100. As would be understood by one ordinarily skilled in the art, these gate conductors could comprise any form of conductor including metals, alloys, polysilicon, etc. In FIG. 1, the gate conductors are labeled NFET and PFET conductors. This indicates that gate conductor 102 will eventually be operating within a NFET and a gate conductor 104 will eventually be operating within a PFET. NFET and PFET transistors are generally not spaced closely together; however, for purposes of illustration, the two transistors have been shown in the same drawing. Line 108 is utilized in the drawings to show a physical separation that would normally occur between such transistors. Further, while the drawings only show two transistors, as would be understood by one ordinarily skilled in the art in light of the specification, the actually manufactured device would include many NFETs and many PFETs. Item 106 illustrates an oxide (e.g., re-oxide) that is usually formed over the gate conductors.

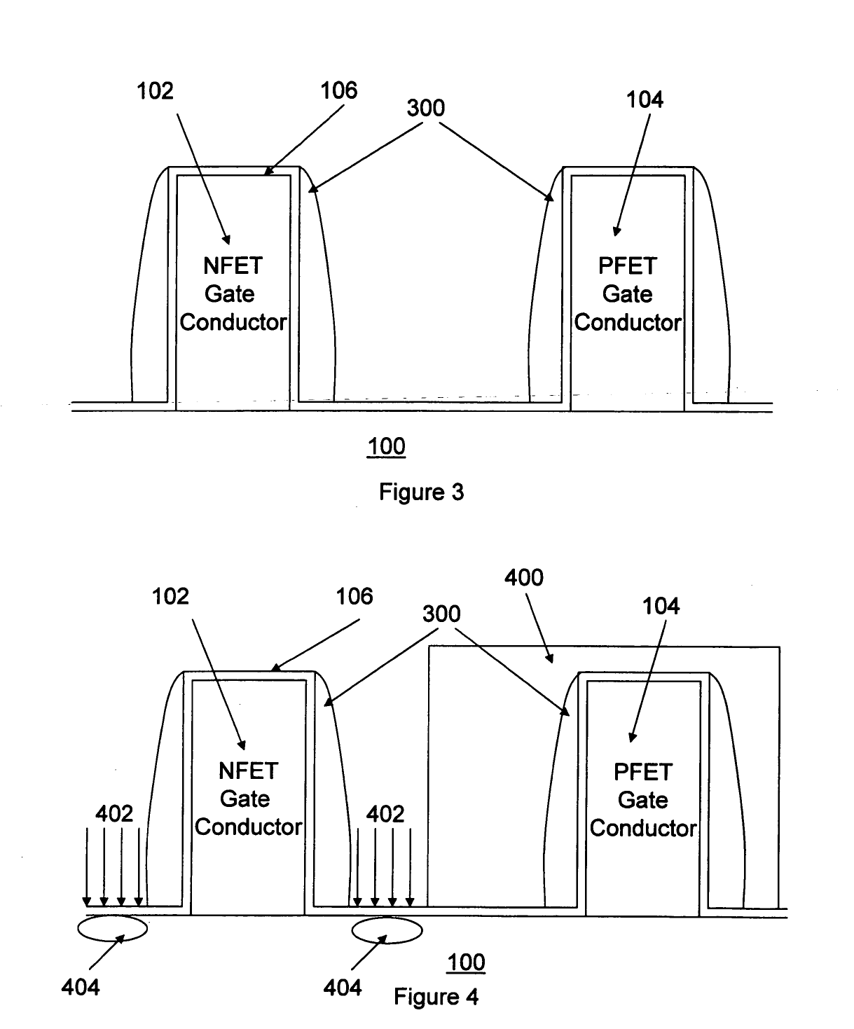

FIG. 2 illustrates the extension implant(s) 200 that are optionally directed into the substrate 100 to form source and drain impurity extensions partially beneath the gate conductors 102, 104. Extension implants are well known to those ordinarily skilled in the art, and a detailed discussion of the same is omitted herefrom. As shown in FIG. 3, the invention forms first spacers 300 adjacent gate conductors 102, 104 on the substrate 100. The spacers utilized with the invention can comprise any spacer material used for transistors, including nitrides, oxides, etc.

Next, as shown in FIG. 4, a first mask 400 is formed over regions of the substrate 100 to be occupied by second-type transistors (e.g. PFETs 104). The masks used with the invention can comprise any well-known mask, including photoresists and similar masking materials. The invention implants a first-type impurity 402 in portions of the substrate 100 adjacent the first spacers 300 of first-type transistors (e.g., NFETs) to form NFET source and drain regions 404. Any appropriate type of impurities can be utilized with the invention, depending upon the specific structure being manufactured. For example, PFETs can utilize boron as an implant species, while NFETs can utilize arsenic. However, the invention is not limited to these specific impurities, and instead the invention is applicable to any form of impurity, whether now known or developed in the future.

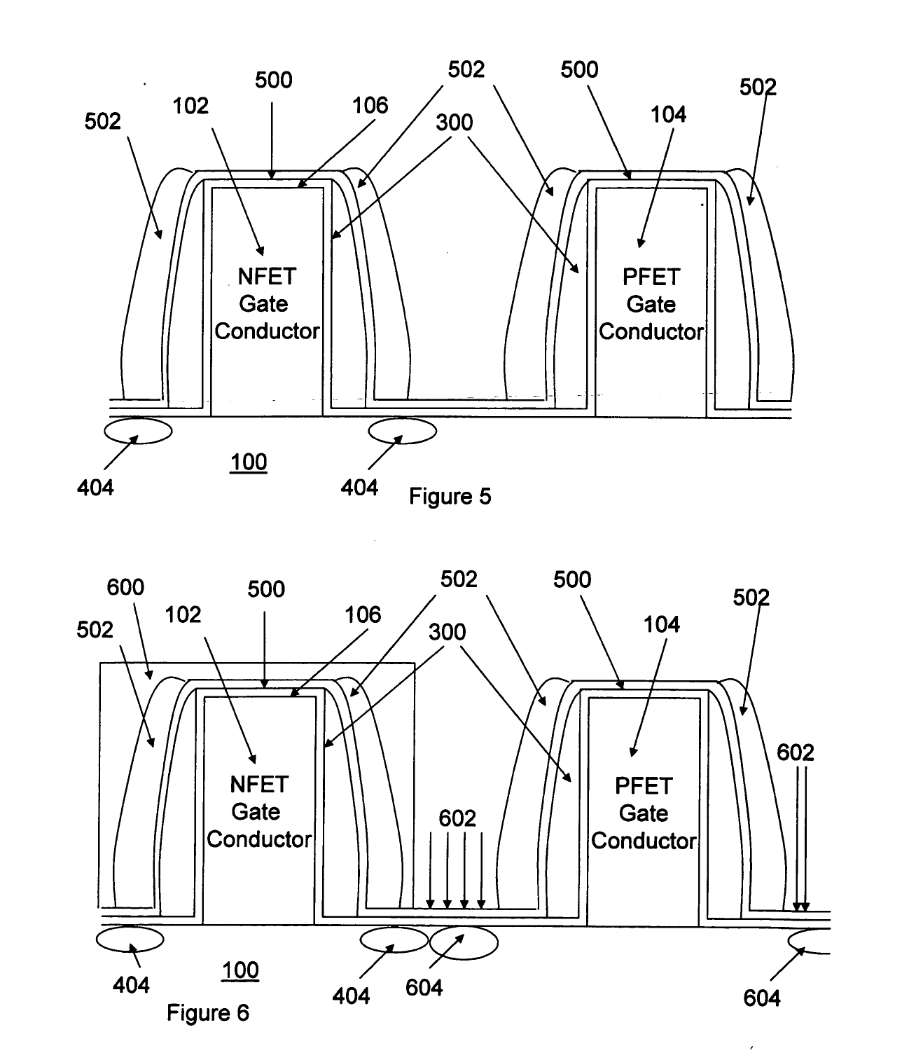

As next shown in FIG. 5, this process continues by removing the first mask 400. Following that, the invention forms an etch stop layer 500 on all of the first spacers 300, on the substrate 100, and on exposed portions of the gate conductors 102, 104. The etch stop layer 500 should be selectively etchable with respect to the spacers and, can comprise, for example, an oxide, etc. Next, second spacers 502 are formed on the etch stop layer 500. After this step, all of the gate conductors 102, 104 have double spacers 300, 502. Then, the invention forms a second mask 600 over regions of the substrate 100 to be occupied by the NFETs, and implants a second-type impurity 602 in portions of the substrate 100 adjacent the second spacers 502 of the PFETs 104 to create PFET source and drain regions 604, as shown FIG. 6.

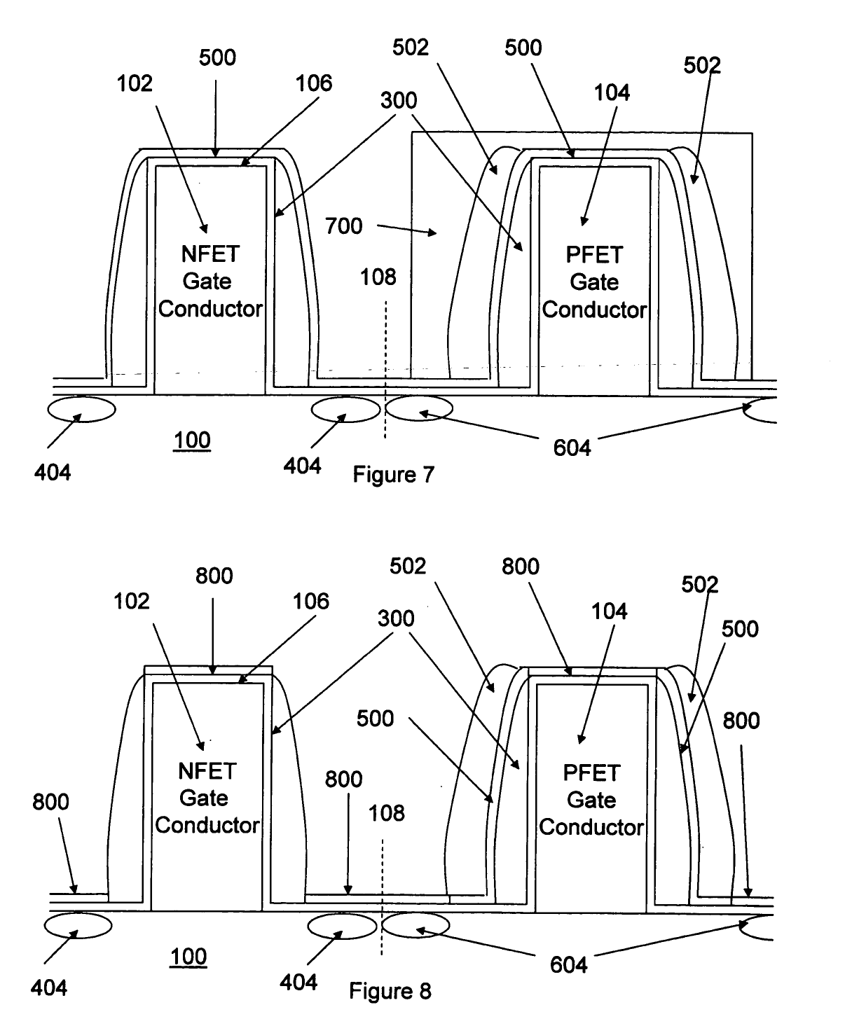

Referring now to FIG. 7, the invention first removes the second mask 600. After this, the invention forms a third mask 700 over regions of the substrate 100 to be occupied by the PFETs 104, and removes the second spacers 502 from the NFETs. Thus, the invention can selectively remove the second spacer over one type of device only. This provides a large advantage in tuning each device to bring the silicide material closer to further from the gate depending on the best performance of that device. By using an anisotropic RIE (Reactive Ion Etch) which etches nitride selectively to oxide, the second nitride spacer can be removed by a dry etch to leave the LTO film and first spacer in place. This all dry removal process is more manufacturable than a wet etch, since it can be controlled to etch at a slower rate and it is not isotropic, as wet etches are.

Following this, as shown in FIG. 8, the invention then removes the third mask 700. Then, the exposed portions of the etch stop layer 500 are removed in a selective removal process that does not affect the underlying spacers 300 (using, for example, a wet or dry HF etching process). The etch stop layer 500 prevents the process of removing the second spacers 502 from affecting the first spacers 300. Note that the etch stop layer 500 will remain between the first spacers 300 and the second spacers 502 on the PFET structures 104. Finally, the exposed areas of the substrate 100 and the gate conductors 102, 104 not covered by the first spacers 300 and the second spacers 502 are silicided to form silicide regions 800.

This process produces an integrated circuit structure that has NFETs 102 and PFETs 104 on the same substrate 100. The NFETs have “first” spacers 300, but the PFETs have the first 300 and “second” 502 spacers. The etch stop layer 500 is positioned between the first spacers 300 and the second spacers 502.

The second spacers 502 are only above the first spacers 300 that are adjacent the second gate conductors 104, and the second spacers 502 are not above the first spacers 300 that are adjacent the first gate conductors 102. Similarly, the etch stop layer 500 is only on the first spacers 300 that are adjacent the second gate conductors 104, and the etch stop layer 500 is not on the first spacers 300 that are adjacent the first gate conductors 102.

First-type impurity implants 404 are in areas of the substrate 100 adjacent the first spacers 300 of the first gate conductors 102, and second-type impurity implants 604 are in areas of the substrate 100 adjacent the second spacers 502 of the second gate conductors 104. Because the second spacers 502 extend further than the first spacers 300 in the PFETs (extend further from their respective gate conductors), the first-type impurity 404 is spaced closer to the first gate conductors 102 than the second-type impurity 604 is spaced from the second gate conductors 104.

This processing, goes from a double to dual spacer (D2D) where a double spacer is formed on the sides of the gates, meaning two distinct nitride spacers (for example) can be formed along side of one another to space the implants at the exact distance from the channel under the gate. Then, the second spacer is removed on only one device (NFET, for example) thus ending up with a different spacer on the NFET than appears on the PFET.

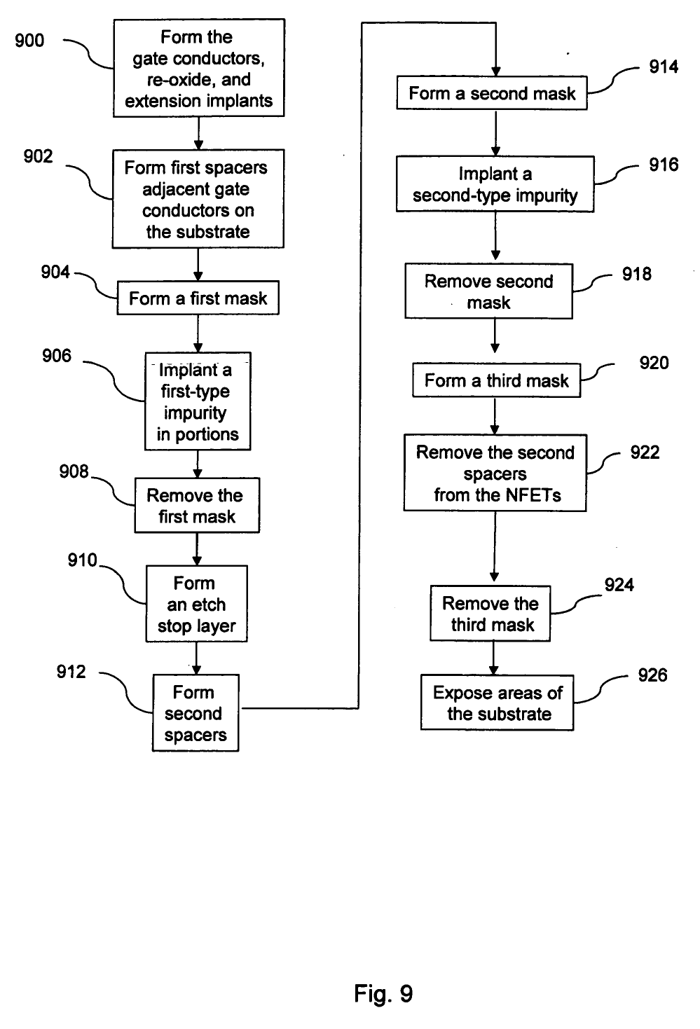

This process is shown in flowchart form in FIG. 9. More specifically, as shown in item 900, the method begins by forming the gate conductors, re-oxide, and extension implants. Next, first spacers are formed adjacent the gate conductors on the substrate (902). In item 904, a first mask is formed over regions of the substrate to be occupied by second-type transistors (e.g. PFETs). The invention implants a first-type impurity in portions of the substrate adjacent the first spacers of first-type transistors (e.g., NFETs) in item 906, and then removes the first mask in item 908.

This process continues by forming an etch stop layer on all of the first spacers, on the substrate, and on exposed portions of the gate conductors (910). Next, second spacers are formed on the etch stop layer (912). After this step, all of the gate conductors have double spacers. Then, in item 914 the invention forms a second mask over regions of the substrate to be occupied by the NFETs. In item 916, the invention implants a second-type impurity in portions of the substrate adjacent the second spacers of the PFETs, and then in item 918 removes the second mask.

After this, as shown in item 920, the invention forms a third mask over regions of the substrate to be occupied by the PFETs. In item 922, the invention removes the second spacers from the NFETs, and then removes the third mask (924). Finally, the exposed areas of the substrate and the gate conductors not covered by the first spacers and the second spacers are silicided (926).

One ordinarily skilled would understand that while the foregoing examples utilizes single and double spacers, the invention is equally applicable to many more spacer layers, so long as a distinction in overall spacer thickness is made between the different types of transistors. Therefore, the exact number of spacers utilized is not as important as insuring that one type of transistor has a larger spacer (which could be formed by using one or more additional spacer layers) so that the impurities for that type of transistor are spaced further from the channel region when compared to a different type of transistor that can exist with the impurity being placed closer to the channel region. Therefore, the invention could potentially use double spacers on one type of transistor and triple or even quadruple spacers on a different type of transistor to achieve the same result as using single and double spacers that are described the above.

Thus, as shown above, the invention provides a method and structure where the first spacer is made and the NFET is implanted, and then a second spacer is formed and the PFET is implanted. A dry nitride etch is then performed which selectively removes the silicon nitride second spacer, stopping selectively on the etch stop. This all dry removal process is more manufacturable than a wet etch, since it can be controlled to etch at a slower rate and is not isotropic. This leaves a double nitride spacer on the PFETs and a single nitride spacer on the NFETs, giving the optimal spacer for each type of device. Furthermore, before silicide formation, the etch stop film on the nitride is removed, leading to a silicide edge very close to the gates for the NFETs, which is optimum for NFETs. The double nitride spacer on the PFETs prevents the silicide from getting too close to the PFET gate, which is optimum for PFETs.

While the invention has been described in terms of preferred embodiments, those skilled in the art will recognize that the invention can be practiced with modification within the spirit and scope of the appended claims.

1. An integrated circuit structure comprising:
a substrate;
first-type transistors on said substrate, wherein said first-type transistors comprise first gate conductors and first spacers adjacent said first gate conductors; and
second-type transistors on said substrate, wherein said second-type transistors comprise second gate conductors, said first spacers adjacent said second gate conductors, and second spacers adjacent said first spacers.

2. The integrated circuit structure in claim 1, wherein said second spacers are only adjacent said first spacers that are adjacent said second gate conductors, and said second spacers are not adjacent said first spacers that are adjacent said first gate conductors.

3. The integrated circuit structure in claim 1, further comprising an etch stop layer positioned between said first spacers and said second spacers, wherein said etch stop layer is only on said first spacers that are adjacent said second gate conductors and said etch stop layer is not on said first spacers that are adjacent said first gate conductors.

4. The integrated circuit structure in claim 1, further comprising:
first-type impurity implants in areas of said substrate adjacent said first spacers of said first gate conductors; and
second-type impurity implants in areas of said substrate adjacent said second spacers of said second gate conductors.

5. The integrated circuit structure in claim 4, wherein said first-type impurity is spaced closer to said first gate conductors than said second-type impurity is spaced from said second gate conductors.

6. The integrated circuit structure in claim 4, wherein said first-type impurity and said second-type impurity comprises source/drain impurities.

7. The integrated circuit structure in claim 1, wherein said first-type transistors comprise n-type field effect transistors (NFETs) and said second-type transistors comprise p-type field effect transistors (PFETs).

8. An integrated circuit structure comprising:
a substrate;
first-type transistors on said substrate, wherein said first-type transistors comprise first gate conductors and first spacers adjacent said first gate conductors; and
second-type transistors on said substrate, wherein said second-type transistors comprise second gate conductors, said first spacers adjacent said second gate conductors, an etch stop layer on said first spacers, and second spacers on said etch stop layer.

9. The integrated circuit structure in claim 8, wherein said second spacers are only adjacent said first spacers that are adjacent said second gate conductors and said second spacers are not adjacent said first spacers that are adjacent said first gate conductors.

10. The integrated circuit structure in claim 8, wherein said etch stop layer is only on said first spacers that are adjacent said second gate conductors and said etch stop layer is not on said first spacers that are adjacent said first gate conductors.

11. The integrated circuit structure in claim 8, further comprising:
first-type impurity implants in areas of said substrate adjacent said first spacers of said first gate conductors; and
second-type impurity implants in areas of said substrate adjacent said second spacers of said second gate conductors.

12. The integrated circuit structure in claim 11, wherein said first-type impurity is spaced closer to said first gate conductors than said second-type impurity is spaced from said second gate conductors.

13. The integrated circuit structure in claim 11, wherein said first-type impurity and said second-type impurity comprises source/drain impurities.

14. The integrated circuit structure in claim 8, wherein said first-type transistors comprise n-type field effect transistors (NFETs) and said second-type transistors comprise p-type field effect transistors (PFETs).

15. A method of simultaneously forming different types of transistors on a substrate, said method comprising:
forming first spacers adjacent gate conductors on said substrate;
implanting a first-type impurity in portions of said substrate adjacent said first spacers of first-type transistors;
forming second spacers adjacent said first spacers such that all of said gate conductors have double spacers;
implanting a second-type impurity in portions of said substrate adjacent said second spacers of second-type transistors;
removing said second spacers from said first-type transistors; and
siliciding exposed areas of said substrate and said gate conductors not covered by said first spacers and said second spacers.

16. The method in claim 15, further comprising, before forming said first spacers, implanting an extension impurity in regions of said substrate adjacent said gate conductors.

17. The method in claim 15, wherein said first-type impurity is spaced closer to said gate conductors than said second-type impurity.

18. The method in claim 15, wherein said first-type impurity and said second-type impurity comprises source/drain impurities.

19. The method in claim 15, wherein said first-type transistors comprise n-type field effect transistors (NFETs) and said second-type transistors comprise p-type field effect transistors (PFETs).

20. The method in claim 15, further comprising forming an etch stop layer between said first spacers and said second spacers, wherein said etch stop layer prevents said process of removing said second spacers from affecting said first spacers.

21. A method of simultaneously forming different types of transistors on a single substrate, said method comprising:
forming first spacers adjacent gate conductors on said substrate;
forming a first mask over regions of said substrate to be occupied by second-type transistors;
implanting a first-type impurity in portions of said substrate adjacent said first spacers of first-type transistors;
removing said first mask;
forming an etch stop layer on all of said first spacers, on said substrate, and on exposed portions of said gate conductors;
forming second spacers on said etch stop layer such that all of said gate conductors have double spacers;
forming a second mask over regions of said substrate to be occupied by said first-type transistors;
implanting a second-type impurity in portions of said substrate adjacent said second spacers of said second-type transistors;
removing said second mask;
forming a third mask over regions of said substrate to be occupied by said second-type transistors;
removing said second spacers from said first-type transistors;
removing said third mask; and
siliciding exposed areas of said substrate and said gate conductors not covered by said first spacers and said second spacers.

22. The method in claim 21, wherein said etch stop layer prevents said process of removing said second spacers from affecting said first spacers.

23. The method in claim 21, further comprising, before forming said first spacers, implanting an extension impurity in regions of said substrate adjacent said gate conductors.

24. The method in claim 21, wherein said first-type impurity and said second-type impurity comprises source/drain impurities.

25. The method in claim 21, wherein said first-type transistors comprise p-type field effect transistors (PFETs) and said second-type transistors comprise n-type field effect transistors (NFETs).
